(19) United States
(12) Patent Application Publication
(10) Pub. No.: US 2006/0035457 A1
(43) Pub. Date: Feb. 16, 2006

(54) Interconnection capacitance reduction

(76) Inventors: Richard J. Carter, Fairview, OR (US); Peter A. Burke, Portland, OR (US); Wilbur G. Catabay, Saratoga, CA (US); Zhihai Wang, Sunnyvale, CA (US); Wei-Jen Hsia, Saratoga, CA (US)

Correspondence Address: LSI LOGIC CORPORATION, 1621 BARBER LANE, MS: D-106, MILPITAS, CA, 95035, US

(21) Appl. No.: 10/915,166

(22) Filed: Aug. 10, 2004

(51) Int. Cl. H01L 21/4763

(52) U.S. Cl. 438/624; 438/638; 438/687; 257/758; 257/760

(57) ABSTRACT

An improvement to a method of fabricating an integrated circuit. All dielectric material that is laterally surrounding an electrically conductive interconnect is removed, while leaving the dielectric material that directly underlies the electrically conductive interconnect. The electrically conductive interconnect is back filled with a low k material, where the low k material provides low capacitance between laterally adjacent electrically conductive interconnects, and the remaining dielectric material underlying the electrically conductive interconnects provides structural support to the electrically conductive interconnects.

### FIELD

This invention relates to the field of integrated circuit fabrication. More particularly, this invention relates to reducing capacitance problems as the spacing between the electrically conductive interconnects of integrated circuits is reduced.

### BACKGROUND

The scaling down of integrated circuit dimensions is driven at least in part by the desire to increase device density, functionality, and speed. As the term is used herein, “integrated circuit” includes devices such as those formed on monolithic semiconducting substrates, such as those formed of group IV materials like silicon or germanium, or group III-V compounds like gallium arsenide, or mixtures of such materials. The term includes all types of devices formed, such as memory and logic, and all designs of such devices, such as MOS and bipolar. The term also comprehends applications such as flat panel displays, solar cells, and charge coupled devices.

However, as integrated circuit dimensions continue to shrink beyond the 130 nanometer technology node, the electrical resistance and parasitic capacitance associated with the high density interconnects, tends to limit the circuit speed for high performance devices. This “slow-down” in device switching speed is commonly known as the “RC delay,” or resistance capacitance delay. As a result of these problems, the integrated circuit fabrication industry has migrated to copper technology in order to generally reduce the resistance of the electrically conductive interconnects that are formed in the integrated circuits.

However, the resistivity component is only one part of the problem. In addition to using copper for the interconnects, the industry is also implementing low dielectric constant (low k) materials to reduce line-to-line capacitance. In order to further reduce the capacitance associated with low k materials, porosity is introduced into the material. By introducing pores into the dielectric material, dielectric constants or k values of about 2.5 and below can be achieved. The integration of copper and porous low k materials in advanced interconnects significantly reduces the RC delay that would otherwise limit performance of sub 90 nanometer devices.

Current processing for advanced interconnects is based on dual damascene processing. The dual damascene process is used to create multi-level high density interconnects by defining the via and trench (also known as the damascene structure) prior to metal wire fill. The dual damascene process is typically either trench first or via first depending on the critical dimensions targeted. In the case of sub quarter micron dimensions, the via first process is generally preferred.

Integration challenges related to copper diffusion into the inter-metal dielectric (IMD) have been met by employing a barrier material prior to copper fill in the damascene structure. As interconnect density increases, the wire size generally decreases, and therefore the amount of barrier material present in a line is preferably reduced in order to maintain low line resistance. Deposition techniques such as atomic layer deposition (ALD) are under investigation as a way to deposit an ultra-thin barrier layer (a few nanometers thick) prior to copper fill. The drawback in the case of porous low k materials is that a process like ALD can easily penetrate into the pores of the dielectric and obstruct the formation of a closed barrier layer, thereby allowing copper to easily diffuse into the IMD. Moreover, during the damascene etch process, additional open pores are created at the vertical via and trench surfaces, which can further facilitate the diffusion of unwanted elements and materials inside the dielectric.

Etching the porous materials and exposing them to photoresist and polymer ashing processes requires sealing treatments to close exposed and opened pores. Pore sealing processes include hydrogen plasma and oxygen plasma treatments, as well as annealing and electron beam treatments, and the deposition of thin insulating polymer films. A pore sealing process tends to cause an increased dielectric constant, which degrades the electrical performance of the integrated circuit by increasing the RC delay of the circuit. Sealing of porous materials with large volume surface pores can also cause shrinkage along the defined trench and via vertical surfaces, causing the top surfaces to bend down, resulting in a rounding of the trench and via edges. Etching and thermal cycling may also affect the mechanical strength and reliability of these layers. Moreover, sharp profiles are difficult to achieve for the via and trench edges and walls due to the low mechanical strength of porous materials.

What is needed, therefore, are interconnect methods and structures that reduce, at least in part, some of the problems described above.

### SUMMARY

The above and other needs are met by an improvement to a method of fabricating an integrated circuit. All dielectric material that is laterally surrounding an electrically conductive interconnect is removed, while leaving the dielectric material that directly underlies the electrically conductive interconnect. The electrically conductive interconnect is back filled with a low k material, where the low k material provides low capacitance between laterally adjacent electrically conductive interconnects, and the remaining dielectric material underlying the electrically conductive interconnects provides structural support to the electrically conductive interconnects.

In this manner, the relatively high k dielectric material is removed from between lateral electrically conductive structures, and replaced with the relatively low k material, so as to reduce the capacitance between such structures. However, the dielectric material can be retained below the electrically conductive interconnects, so as to provide structural support for the electrically conductive interconnects.

In various embodiments, the dielectric material is a silicon oxide, the electrically conductive interconnect is formed substantially of copper, and the low k material has a dielectric constant of less than about three. Preferably, the electrically conductive interconnect is a dual damascene structure, where a via portion of the dual damascene structure underlies an interconnect portion of the dual damascene structure, and the via portion is surrounded with the dielectric material that underlies the interconnect portion. In some embodiments the dielectric material that directly underlies the electrically conductive interconnect is removed, to leave a void underlying the electrically conductive interconnect. In other embodiments the dielectric material that directly underlies the electrically conductive interconnect is removed, and the electrically conductive interconnect is under filled with the low k material. An integrated circuit formed according to the method described herein is also disclosed.

According to another aspect of the invention, there is described a method of fabricating electrically conductive interconnects in an integrated circuit. A bottom etch stop layer is formed on the integrated circuit and a dielectric layer is formed on the bottom etch stop layer. A trench is etched in the dielectric layer, where the trench has an overhang. The trench is filled with an electrically conductive material, thereby forming the electrically conductive interconnects. The dielectric material that laterally surrounds the electrically conductive material in the trench is removed, while leaving the dielectric material that directly underlies the overhang. The electrically conductive material is back filled with a low k material, where the low k material provides low capacitance between laterally adjacent electrically conductive interconnects, and the remaining dielectric material underlying the overhang provides structural support to the electrically conductive interconnects. The steps are repeated to form as many layers of the electrically conductive interconnects as desired.

According to yet another aspect of the invention there is described a method of fabricating electrically conductive interconnects in an integrated circuit, where a bottom etch stop layer is formed on the integrated circuit, a first dielectric layer is formed on the bottom etch stop layer, a center etch stop layer is formed on the first dielectric layer, and a second dielectric layer is formed on the center etch stop layer. A dual damascene trench is etched in the second dielectric layer, the center etch stop layer, the first dielectric layer, and the bottom etch stop layer. The dual damascene trench has an overhang. The dual damascene trench is filled with an electrically conductive material, thereby forming the electrically conductive interconnects.

The second dielectric layer and the center etch stop layer are completely removed, and portions of the first dielectric layer that laterally surround the electrically conductive material in the dual damascene trench are removed, while leaving portions of the first dielectric layer that directly underlie the overhang. The electrically conductive material is back filled with a low k material, where the low k material provides low capacitance between laterally adjacent electrically conductive interconnects, and the remaining dielectric material underlying the overhang provides structural support to the electrically conductive interconnects. The steps are repeated to form as many layers of the electrically conductive interconnects as desired.

### BRIEF DESCRIPTION OF THE DRAWINGS

Further advantages of the invention are apparent by reference to the detailed description when considered in conjunction with the figures, which are not to scale so as to more clearly show the details, wherein like reference numbers indicate like elements throughout the several views, and wherein:

FIG. 1 is a cross sectional depiction of an integrated circuit, where etch stop layers and inter metal dielectric layers have been formed.

FIG. 2 is a cross sectional depiction of an integrated circuit, where the etch stop layers and inter metal dielectric layers have been etched.

FIG. 3 is a cross sectional depiction of an integrated circuit, where boundary layers and electrically conductive interconnects have been formed in the inter metal dielectric layers.

FIG. 4 is a cross sectional depiction of an integrated circuit, where the boundary layers and interconnects have been planarized.

FIG. 5 is a cross sectional depiction of an integrated circuit, where the interconnects have received an option encapsulating layer.

FIG. 6 is a cross sectional depiction of an integrated circuit, where the dielectric layer on the same level as the M1 interconnect has been removed.

FIG. 7 is a cross sectional depiction of an integrated circuit, where the optional center etch stop layer and a portion of the dielectric layer on the same level as the via 1 has been removed.

FIG. 8 is a cross sectional depiction of an integrated circuit, where all of the dielectric layer on the same level as the via 1 has been removed, except for that portion of the dielectric layer that directly underlies the M1 interconnect.

FIG. 9 is a cross sectional depiction of an integrated circuit, where all of the dielectric layer on the same level as the via 1 has been removed.

FIG. 10 is a cross sectional depiction of an integrated circuit, where the M1 and via 1 structures have been back filled with a low k material.

FIG. 11 is a cross sectional depiction of an integrated circuit, where the low k material surrounding the via 1 and the M1 interconnect has been planarized.

FIG. 12 is a cross sectional depiction of an integrated circuit, where the M1 interconnect has received an encapsulating layer.

FIG. 13 is a cross sectional depiction of an integrated circuit, where the M1 interconnect has received an encapsulating layer that also functions as a bottom etch stop for the next interconnect level.

FIG. 14 is a cross sectional depiction of an integrated circuit, where several interconnect levels have been formed, where the interconnects are mechanically supported by the remaining portions of the inter metal dielectric layers that surround the vias and underlie the interconnects.

FIG. 15 is a cross sectional depiction of an integrated circuit, where several interconnect levels have been formed, where some of the interconnects are mechanically supported by the remaining portions of the inter metal dielectric layers that surround the vias and underlie the interconnects, some of the interconnects are supported by the low k material that was back filled around the vias and the interconnects, and some of the interconnects are not physically supported by any dielectric material.

### DETAILED DESCRIPTION

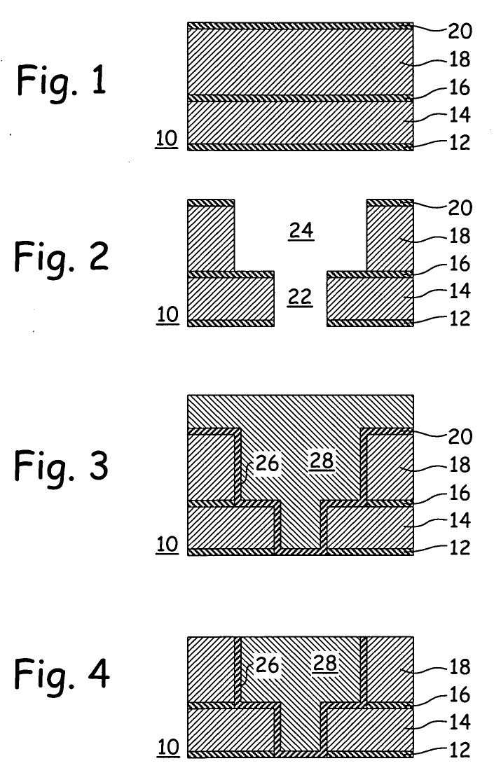

The various embodiments of the present invention preferably use a sacrificial inter metal layer material to define interconnect trench lines and via structures. A good candidate for the sacrificial inter metal layer is a silicon oxide based material, such as SiO₂, fluorinated oxides, and SiOCH. FIGS. 1-4 generally depict the steps by which a dual damascene via and interconnect combination are formed. First, a bottom etch stop layer is preferably formed on the integrated circuit 10. It is appreciated that there are preferably many additional layers below the bottom etch stop layer 12. Such layers are formed during what is typically referred to as front end process, and are not depicted here so as to direct attention more fully to those steps of the invention which are more novel.

An inter metal dielectric layer 14 is next formed on the integrated circuit 10. The dielectric layer 14 is preferably that layer in which the via structure will be formed. On top of the dielectric layer 14 there is optionally formed a center etch stop layer 16. Overlying the optional center etch stop layer 16 there is formed another dielectric layer 18, in which the interconnect structure will preferably be formed. Overlying the dielectric layer 18 is another etch stop layer 20, which is preferably used to help pattern the trench for the interconnect structure to be formed. It is appreciated that similar layers can be formed of the same materials, or of different materials. However, in the preferred embodiments, all etch stop layers are formed of the same material, and all dielectric layers are formed of the same materials, although not of the same material as that used for the etch stop layers. In this manner, processing is generally simplified.

The sacrificial stack as depicted in FIG. 1 can employ an optional center etch stop layer 16 and an optional bottom etch stop layer 12 to improve the robustness of the process. However, these etch stop layers 12 and 16 are not strictly necessary. When a center etch stop layer 16 is not used, a single combined dielectric layer 14-18 is formed. SiC and SiN are preferred as etch stop layer materials.

As depicted in FIG. 2, the dual damascene trench for the interconnect 24 and the via 22 is preferably etched, using standard processing. The trench is lined with an electrically conductive barrier layer material 26, and filled with an electrically conductive plug material, which is preferably a metal, and is most preferably copper, as depicted in FIG. 3. The resulting via and interconnect structure is then preferably planarized, as depicted in FIG. 4.

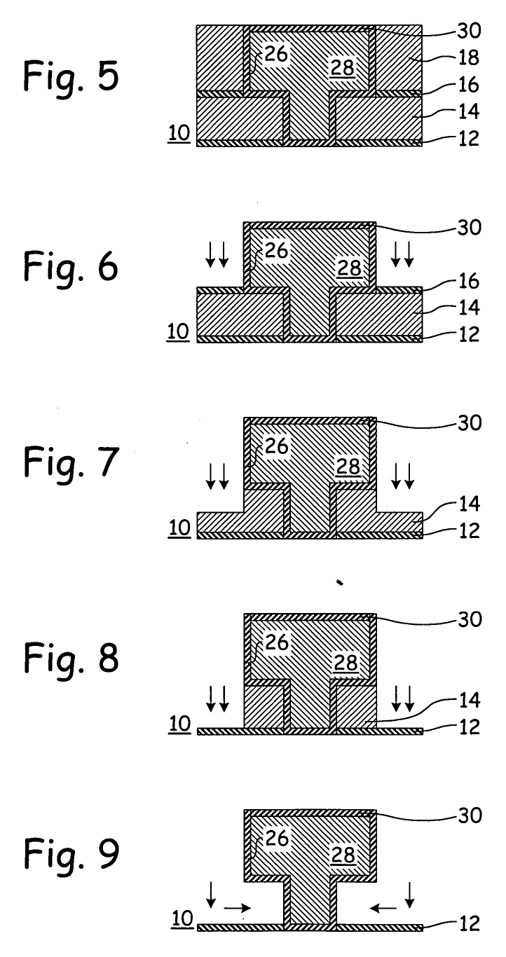

After completing conventional dual damascene processing in the sacrificial stack, a capping layer 30 is selectively deposited on the exposed copper surface, as depicted in FIG. 5, to prevent copper diffusion into the new inter metal dielectric layer and protect the copper surface during further processing. The optional encapsulation layer 30 is preferably formed of the same material as the barrier layer 26, although it need not be.

The sacrificial inter metal layer 18 is then preferably removed, as depicted in FIG. 6. A dry etch process is most preferably used to etch a desired depth into the sacrificial inter metal layer 18, either leaving the center etch stop layer 16 and sacrificial layer 14 intact beneath it as depicted in FIG. 6, or removing the center etch stop layer 16 and etching further into the sacrificial layer 14 as depicted in FIG. 7, or etching further to the bottom etch stop layer 12 as depicted in FIG. 8. If the optional center etch stop layer 16 is used, then a wet etch can be used to etch the dielectric layer 18, and the center etch stop layer 16. A wet etch is preferably not used for the etching process of the dielectric layer 14, so as to not remove any of the dielectric material 14 that is disposed directly beneath the trench and around the vias. In this manner, the remaining dielectric material 14 that underlies the interconnect structure can be used to mechanically support the interconnect structure.

However, one embodiment uses either a wet etch process or a combination of dry etch followed by a wet etch to completely remove the center etch stop layer 16 and all of the dielectric material 14, leaving behind a freestanding interconnect and via structure as depicted in FIG. 9. However, the structure as depicted in FIG. 8 is the preferred embodiment of the present invention, from the standpoint of process robustness and mechanical support of the interconnect via structure, while also achieving a line-to-line capacitance very close to what would be achieved using the embodiment of FIG. 9.

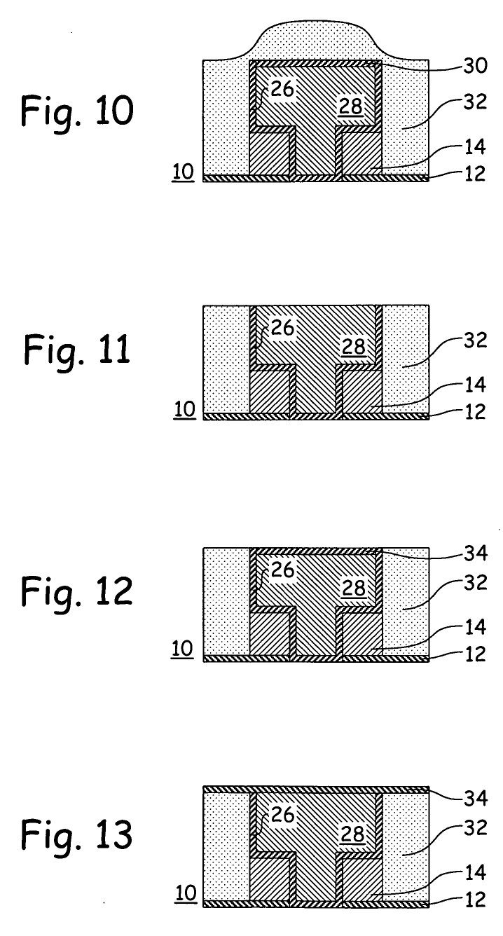

After etching the sacrificial inter-metal layers 14, 16, and 18, a porous low k material 32 is preferably deposited, as depicted in FIG. 10, to act as the final inter metal dielectric material. The porous low k material preferably has sufficient reflow properties to more easily fill the areas between dense interconnect structures. The new material 32 not only fills the spaces between interconnect structures, but also tends to be deposited on top of the structures. As a result, a planarization step may be necessary to polish the low k material 32 to the trench surface, resulting in a planar topography as depicted in FIG. 11.

After cleaning up from the planarization process, an anneal may be needed to dry out the porous low k material 32. A capping layer or diffusion barrier layer 34 is preferably deposited over the exposed interconnect, as depicted in FIG. 12, or most preferably over the enter surface of the interconnect and low k material 32 as depicted in FIG. 13, to act as a bottom etch stop for the next metallization layer. Thus, the steps as described above in regard to the formation of the dual damascene structure depicted are preferably repeated as desired to form additional interconnect layers. A copper oxide pre-clean is preferably immediately performed before deposition of the capping layer or diffusion barrier layer 34. A diffusion barrier layer 34 of SiC or SiN is preferred at this stage over just a capping layer, because it acts as the bottom etch stop layer for the next inter metal dielectric level, in addition to acting as a diffusion barrier for the exposed interconnect material after planarization of the low k material 32.

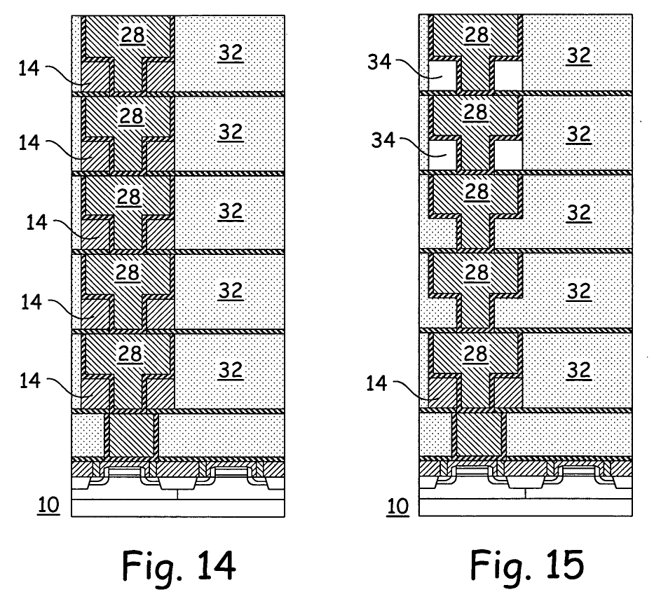

FIG. 14 depicts an interconnect stack where several interconnect layers have been formed according to the processes described above. As depicted, the denser material 14 which underlies the interconnects provides structural support for the interconnects, while the low k material 32 generally reduces RC losses between horizontally adjacent lines. FIG. 15 depicts alternate embodiments, where the dielectric material 14 was removed from underneath some of the interconnects as depicted in FIG. 9, leaving the interconnects as air bridges with voids 34 below them. Additionally depicted in FIG. 15 are layers where the dielectric material 14 was removed from under the interconnects as depicted in FIG. 9, and the space underlying the interconnect was back filled with the low k material 32. Although neither the void nor the low k material 32 provides the structural support that is provided by the dielectric material 14, some of the interconnect structures do not require as much support as others might, and the void and the low k material 32 tend to further reduce the RC effects.

The process as described above has several advantages, including the introduction of ultra low k materials in 90 nanometer technology, with fewer integration issues. Development costs for back end of line etch and strip processes are reduced. The damascene process remains generally the same, because the same sacrificial inter-metal layer may be used across technology generations. The sacrificial inter-metal layer need not be porous, therefore the issue of pore sealing after etch can be eliminated. Use of higher quality and denser sacrificial inter-metal layers allows use of ALD for copper barrier deposition, which allows for the copper barrier layer to be controllably thin, thereby decreasing line resistivity. Significantly improved via and trench profiles are achieved due to the interconnect definition being done in a dense layer rather than a porous material with low mechanical strength. The process can include a trench etch stop, then later eliminate it between lines. These methods generally improve process robustness without increasing the effective dielectric constant.

One alternate approach to the methods described above is to use a single damascene process, where the via is formed in the sacrificial material and then the sacrificial material is removed and replaced with porous low k material and polished back, followed by deposition of the sacrificial material at the trench level. The trench line is then formed and the sacrificial material is removed and replaced with porous low k material. One consequence of this embodiment is the need to remove the trench level sacrificial material without adversely affecting the via level porous low k material. An etch stop could be included prior to the trench level sacrificial material deposition, but then the etch stop layer in the dielectric stack would increase the effective dielectric constant, and generally increase line-to-line capacitance. Moreover, the single damascene approach could result in an increase in resistance between the trench line and via if the copper clean step is not sufficient prior to trench fill. These issues would be avoided with the dual damascene process as described above.

The foregoing description of preferred embodiments for this invention has been presented for purposes of illustration and description. It is not intended to be exhaustive or to limit the invention to the precise form disclosed. Obvious modifications or variations are possible in light of the above teachings. The embodiments are chosen and described in an effort to provide the best illustrations of the principles of the invention and its practical application, and to thereby enable one of ordinary skill in the art to utilize the invention in various embodiments and with various modifications as are suited to the particular use contemplated. All such modifications and variations are within the scope of the invention as determined by the appended claims when interpreted in accordance with the breadth to which they are fairly, legally, and equitably entitled.

What is claimed is:

1. In a method of fabricating an integrated circuit, the improvement comprising the steps of:
removing all dielectric material that is laterally surrounding an electrically conductive interconnect, while leaving the dielectric material that directly underlies the electrically conductive interconnect, and
back filling around the electrically conductive interconnect with a low k material,
where the low k material provides low capacitance between laterally adjacent electrically conductive interconnects, and the remaining dielectric material underlying the electrically conductive interconnects provides structural support to the electrically conductive interconnects.

2. The method of claim 1, wherein the dielectric material is a silicon oxide.

3. The method of claim 1, wherein the electrically conductive interconnect is formed substantially of copper.

4. The method of claim 1, wherein the low k material has a dielectric constant of less than about three.

5. The method of claim 1, wherein the electrically conductive interconnect is a dual damascene structure, where a via portion of the dual damascene structure underlies an interconnect portion of the dual damascene structure, and the via portion is surrounded with the dielectric material that underlies the interconnect portion.

6. The method of claim 1, further comprising the step of removing the dielectric material that directly underlies the electrically conductive interconnect, to leave a void underlying the electrically conductive interconnect.

7. The method of claim 1, further comprising the steps of removing the dielectric material that directly underlies the electrically conductive interconnect, and back filling under the electrically conductive interconnect with the low k material.

8. An integrated circuit formed according to the method of claim 1.

9. A method of fabricating electrically conductive interconnects in an integrated circuit, the method comprising the steps of:
forming a bottom etch stop layer on the integrated circuit,
forming a dielectric layer on the bottom etch stop layer,
etching a trench in the dielectric layer, where the trench has an overhang,
filling the trench with an electrically conductive material, thereby forming the electrically conductive interconnects,
removing the dielectric material that laterally surrounds the electrically conductive material in the trench, while leaving the dielectric material that directly underlies the overhang,
back filling around the electrically conductive material with a low k material, where the low k material provides low capacitance between laterally adjacent electrically conductive interconnects, and the remaining dielectric material underlying the overhang provides structural support to the electrically conductive interconnects, and
repeating the steps to form as many layers of the electrically conductive interconnects as desired.

10. The method of claim 9, wherein the dielectric material is a silicon oxide.

11. The method of claim 9, wherein the electrically conductive interconnect is a dual damascene structure, where a via portion of the dual damascene structure underlies an interconnect portion of the dual damascene structure, and the via portion is surrounded with the dielectric material that underlies the interconnect portion.

12. The method of claim 9, further comprising the step of removing the dielectric material that directly underlies the electrically conductive interconnect, to leave a void underlying the electrically conductive interconnect.

13. The method of claim 9, further comprising the steps of removing the dielectric material that directly underlies the electrically conductive interconnect, and back filling under the electrically conductive interconnect with the low k material.

14. An integrated circuit formed according to the method of claim 9.

15. A method of fabricating electrically conductive interconnects in an integrated circuit, the method comprising the steps of:
forming a bottom etch stop layer on the integrated circuit,
forming a first dielectric layer on the bottom etch stop layer,
forming a center etch stop layer on the first dielectric layer,
forming a second dielectric layer on the center etch stop layer,
etching a dual damascene trench in the second dielectric layer, center etch stop layer, first dielectric layer, and bottom etch stop layer, where the dual damascene trench has an overhang,
filling the dual damascene trench with an electrically conductive material, thereby forming the electrically conductive interconnects,
completely removing the second dielectric layer,
completely removing the center etch stop layer,
removing portions of the first dielectric layer that laterally surround the electrically conductive material in the dual damascene trench, while leaving portions of the first dielectric layer that directly underlie the overhang,
back filling around the electrically conductive material with a low k material, where the low k material provides low capacitance between laterally adjacent electrically conductive interconnects, and the remaining dielectric material underlying the overhang provides structural support to the electrically conductive interconnects, and
repeating the steps to form as many layers of the electrically conductive interconnects as desired.

16. The method of claim 15, wherein the dielectric material is a silicon oxide.

17. The method of claim 15, wherein the electrically conductive interconnect is formed substantially of copper.

18. The method of claim 15, further comprising the step of removing the dielectric material that directly underlies the electrically conductive interconnect, to leave a void underlying the electrically conductive interconnect.

19. The method of claim 15, further comprising the steps of removing the dielectric material that directly underlies the electrically conductive interconnect, and back filling under the electrically conductive interconnect with the low k material.

20. An integrated circuit formed according to the method of claim 15.
